(19) United States
(12) Patent Application Publication
(10) Pub. No.: US 2022/0366109 A1
(43) Pub. Date: Nov. 17, 2022

(54) METHOD TO GENERATE AND TRAINING MODELS IN A RETAIL ENVIRONMENT

(71) Applicant: AiFi Corp, Santa Clara, CA (US)

(72) Inventors: Steve Gu, Santa Clara, CA (US); Ying Zheng, Santa Clara, CA (US); Brian Bates, Santa Clara, CA (US)

(73) Assignee: AiFi Corp, Santa Clara, CA (US)

(21) Appl. No.: 17/317,898

(22) Filed: May 12, 2021

(51) Int. Cl. G06F 30/27; G06N 3/00; G06Q 30/06

(52) U.S. Cl. CPC G06F 30/27; G06N 3/006; G06Q 30/0641

(57) ABSTRACT

This application relates to systems, methods, devices, and other techniques for methods to generate and training models within a retail environment

### BACKGROUND OF THE INVENTION

This application relates to systems, methods, devices, and other techniques that can be utilized to generate models within a retail environment and perform simulation to perfect these models.

Methods and apparatus to generate models for testing and training neural networks in a retail store to monitor products and customers are in practice. However, generating models by visual reality platforms within a retail environment is new. Furthermore, these techniques and methods can be combined with recently developed AI and machine learning and make the purchase process more accurate and efficient.

Therefore, it is desirable to have new systems, methods, devices, and other techniques to generate models within a retail environment and perform simulation to perfect these models in a retail environment.

### SUMMARY OF THE INVENTION

In some embodiments, the invention is related to a method of generating models, comprising a step of generating a first set of simulation data, wherein the first set of simulation data describes products, wherein the first set of simulation data comprises a first set of annotations, wherein the first set of annotations comprises data of product size, product shape, and possibility of one product partially covering another product.

In some embodiments, the method is comprising a step of generating a second set of simulation data, wherein the second set of simulation data describes store shelves, wherein the second set of simulation data comprises a second set of annotations, wherein the second set of annotation comprises data of height, width, length, color, material of the store shelves.

In some embodiments, the method comprises a step of generating a third set of simulation data, wherein the third set of simulation data describes store environments, wherein the third set of simulation data comprises a third set of annotations, wherein the third set of annotation comprises data of store ceiling, store setup, store floor and store lighting, wherein the data of the store lighting comprises data of color, intensity and style of the store lighting.

In some embodiments, the method comprises a step of generating a fourth set of simulation data, where the fourth set of simulation data describes one or more customers, wherein the fourth set of simulation data comprises a fourth set of annotations, wherein the fourth set of annotation comprises data of height, weight, clothing style, hair color, gender, and interactions of the one or more customers with the products, the store shelves and the store environments.

In some embodiments, the method comprises a step of generating a plurality of smart objects from the first set of simulation data, the second set of simulation data, the third set of simulation data, and the fourth set of simulation data, wherein each smart object represents a respective element of a virtual shopping environment that comprises at least one of a floor, a shelf, a sign, and a product, wherein the each smart object comprises a fifth set of annotations, wherein the fifth set of annotations comprises data of targeted location and targeted customer base of the retail store.

In some embodiments, the method comprises a step of training and tuning the fifth set of annotations in a virtual reality simulation platform.

In some embodiments, the method comprises a step of testing the plurality of smart objects in a simulated automatic store with an average amount of customers in the retail store, wherein the average amount is estimated from data gathered in surveys conducted in a local area.

In some embodiments, the method comprises a step of testing the plurality of smart objects in another simulated automatic store with more than one hundred times of the average amount of customers in the retail store.

In some embodiments, the method comprises a step of testing the plurality of smart objects in a third simulated store with a size of ten times larger than that of the retail store.

These and other aspects, their implementations and other features are described in detail in the drawings, the description and the claims.

### BRIEF DESCRIPTION OF THE DRAWINGS

FIG. 1 shows an example of a method to generate and training models.

FIG. 2 shows an example of another method to generate and training models.

FIG. 3 shows another example of a third method to generate and training models.

### DETAILED DESCRIPTION OF THE INVENTION

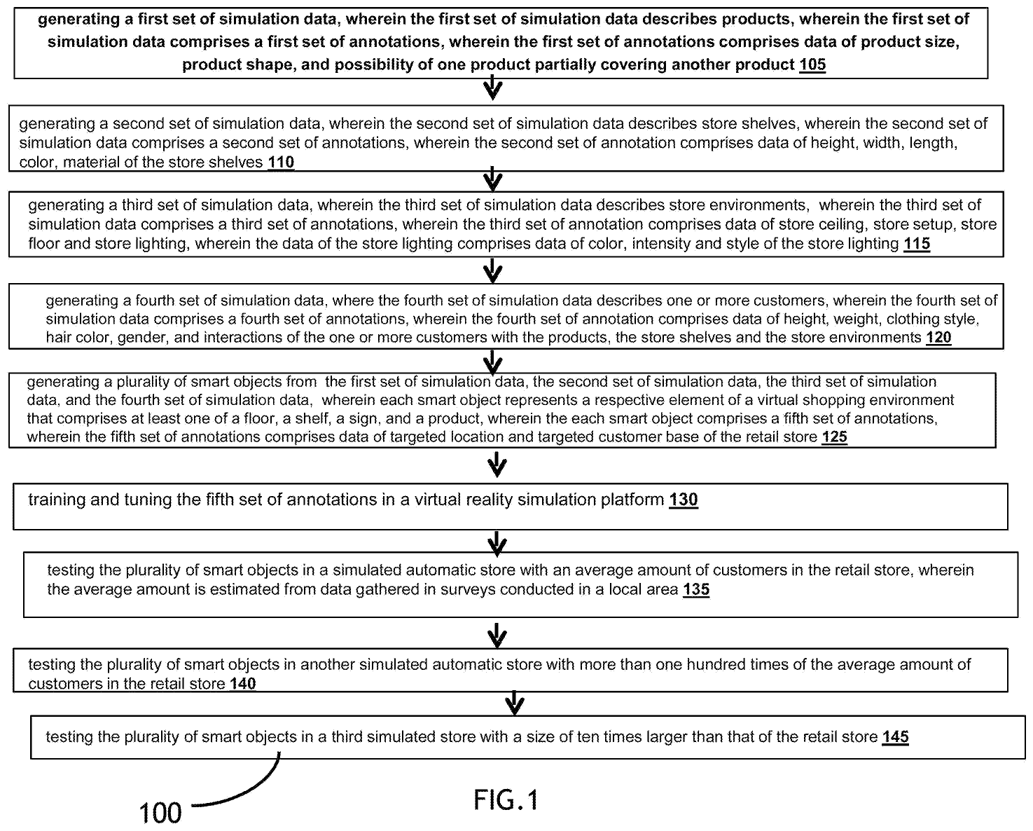

FIG. 1 shows an example of a method to generate and training models

In some embodiments, the invention is related to a method 100 of generating models, comprising a step 105 of generating a first set of simulation data, wherein the first set of simulation data describes products, wherein the first set of simulation data comprises a first set of annotations, wherein the first set of annotations comprises data of product size, product shape, and possibility of one product partially covering another product.

In some embodiments, the method is comprising a step 110 of generating a second set of simulation data, wherein the second set of simulation data describes store shelves, wherein the second set of simulation data comprises a second set of annotations, wherein the second set of annotation comprises data of height, width, length, color, material of the store shelves.

In some embodiments, the method comprises a step 115 of generating a third set of simulation data, wherein the third set of simulation data describes store environments, wherein the third set of simulation data comprises a third set of annotations, wherein the third set of annotation comprises data of store ceiling, store setup, store floor and store lighting, wherein the data of the store lighting comprises data of color, intensity and style of the store lighting.

In some embodiments, the method comprises a step 120 of generating a fourth set of simulation data, where the fourth set of simulation data describes one or more customers, wherein the fourth set of simulation data comprises a fourth set of annotations, wherein the fourth set of annotation comprises data of height, weight, clothing style, hair color, gender, and interactions of the one or more customers with the products, the store shelves and the store environments.

In some embodiments, the method comprises a step 125 of generating a plurality of smart objects from the first set of simulation data, the second set of simulation data, the third set of simulation data, and the fourth set of simulation data, wherein each smart object represents a respective element of a virtual shopping environment that comprises at least one of a floor, a shelf, a sign, and a product, wherein the each smart object comprises a fifth set of annotations, wherein the fifth set of annotations comprises data of targeted location and targeted customer base of the retail store.

In some embodiments, the method comprises a step 130 of training and tuning the fifth set of annotations in a virtual reality simulation platform.

In some embodiments, the method comprises a step 135 of testing the plurality of smart objects in a simulated automatic store with an average amount of customers in the retail store, wherein the average amount is estimated from data gathered in surveys conducted in a local area.

In some embodiments, the method comprises a step 140 of testing the plurality of smart objects in another simulated automatic store with more than one hundred times of the average amount of customers in the retail store.

In some embodiments, the method comprises a step 145 of testing the plurality of smart objects in a third simulated store with a size of ten times larger than that of the retail store.

In some embodiments, the style of the store lighting includes a style of disco lighting.

In some embodiments, the first set of annotations comprise transparency of a group of products.

In some embodiments, the fourth set of annotations further comprises total number and total value of products in a simulated store environment.

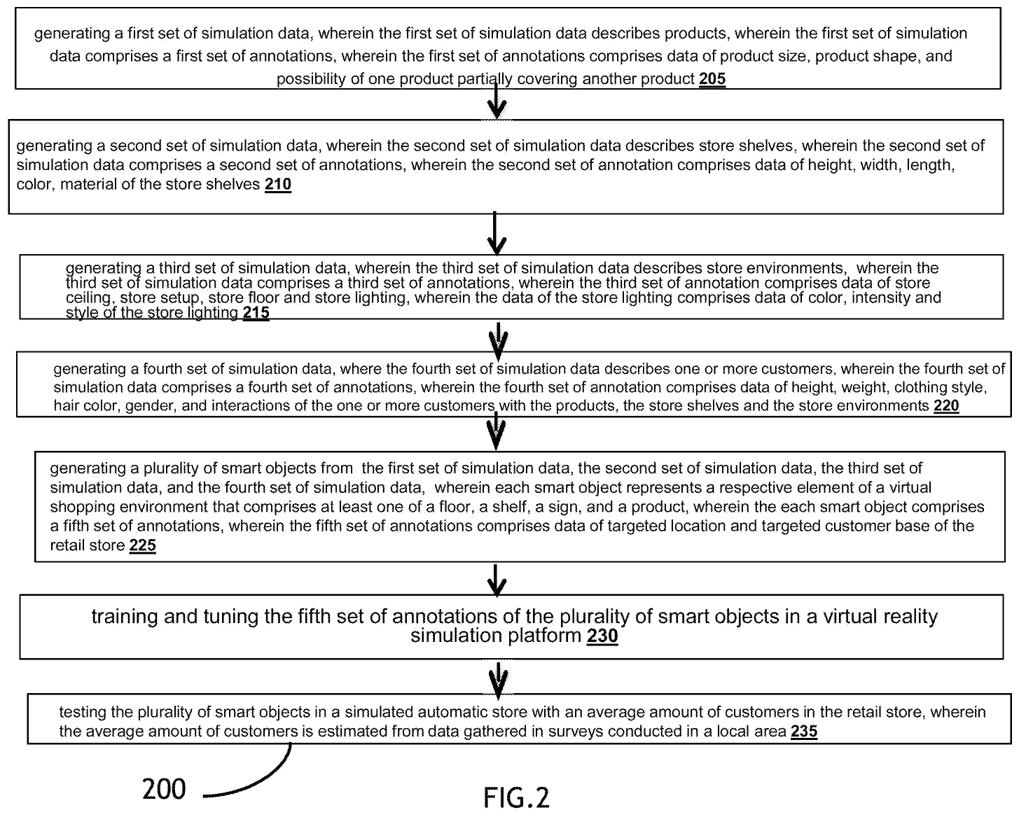

FIG. 2 shows an example of another method to generate and training models.

In some embodiments, A method 200 for simulating a retail store, comprising: a step 205 of generating a first set of simulation data, wherein the first set of simulation data describes products, wherein the first set of simulation data comprises a first set of annotations, wherein the first set of annotations comprises data of product size, product shape, and possibility of one product partially covering another product.

In some embodiments, the method comprises a step 210 of generating a second set of simulation data, wherein the second set of simulation data describes store shelves, wherein the second set of simulation data comprises a second set of annotations, wherein the second set of annotation comprises data of height, width, length, color, material of the store shelves.

In some embodiments, the method comprises a step 215 of generating a third set of simulation data, wherein the third set of simulation data describes store environments, wherein the third set of simulation data comprises a third set of annotations, wherein the third set of annotation comprises data of store ceiling, store setup, store floor and store lighting, wherein the data of the store lighting comprises data of color, intensity and style of the store lighting.

In some embodiments, the method comprises a step 220 of generating a fourth set of simulation data, where the fourth set of simulation data describes one or more customers, wherein the fourth set of simulation data comprises a fourth set of annotations, wherein the fourth set of annotation comprises data of height, weight, clothing style, hair color, gender, and interactions of the one or more customers with the products, the store shelves and the store environments.

In some embodiments, the method comprises a step 225 of generating a plurality of smart objects from the first set of simulation data, the second set of simulation data, the third set of simulation data, and the fourth set of simulation data, wherein each smart object represents a respective element of a virtual shopping environment that comprises at least one of a floor, a shelf, a sign, and a product, wherein the each smart object comprises a fifth set of annotations, wherein the fifth set of annotations comprises data of targeted location and targeted customer base of the retail store.

In some embodiments, the method comprises a step 230 of training and tuning the fifth set of annotations of the plurality of smart objects in a virtual reality simulation platform.

In some embodiments, the method comprises a step 235 of testing the plurality of smart objects in a simulated automatic store with an average amount of customers in the retail store, wherein the average amount of customers is estimated from data gathered in surveys conducted in a local area.

In some embodiments, the style of the store lighting includes a style of disco lighting.

In some embodiments, the first set of annotations comprise transparency of a group of products.

In some embodiments, the fourth set of annotations further comprises total number and total value of products in a simulated store environment.

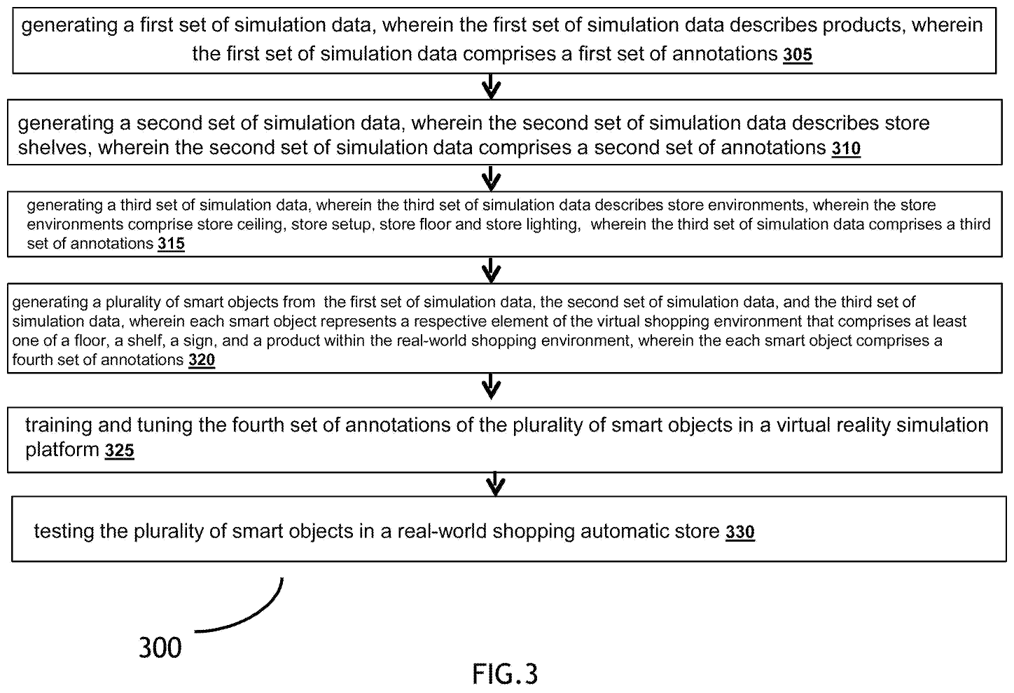

FIG. 3 shows another example of a third method to generate and training models.

In some implementations, a method 300 to generate models, comprising of a step 305 of generating a first set of simulation data, wherein the first set of simulation data describes products, wherein the first set of simulation data comprises a first set of annotations.

In some embodiments, the method comprises a step 310 of generating a second set of simulation data, wherein the second set of simulation data describes store shelves, wherein the second set of simulation data comprises a second set of annotations.

In some embodiments, the method comprises a step 315 of generating a third set of simulation data, wherein the third set of simulation data describes store environments, wherein the store environments comprise store ceiling, store setup, store floor and store lighting, wherein the third set of simulation data comprises a third set of annotations.

In some embodiments, the method comprises a step 320 of generating a plurality of smart objects from the first set of simulation data, the second set of simulation data, and the third set of simulation data, wherein each smart object represents a respective element of the virtual shopping environment that comprises at least one of a floor, a shelf, a sign, and a product within the real-world shopping environment, wherein the each smart object comprises a fourth set of annotations.

In some embodiments, the method comprises a step 325 of training and tuning the fourth set of annotations of the plurality of smart objects in a virtual reality simulation platform.

In some embodiments, the method comprises a step 330 of testing the plurality of smart objects in a real-world shopping automatic store.

In some embodiments, the style of the store lighting includes a style of disco lighting.

In some embodiments, the first set of annotations comprise transparency of a group of products.

In some embodiments, the fourth set of annotations further comprises total number and total value of products in a simulated store environment.

1. A method for simulating a retail store, comprising:
generating a first set of simulation data, wherein the first set of simulation data describes products, wherein the first set of simulation data comprises a first set of annotations, wherein the first set of annotations comprises data of product size, product shape, and possibility of one product partially covering another product;
generating a second set of simulation data, wherein the second set of simulation data describes store shelves, wherein the second set of simulation data comprises a second set of annotations, wherein the second set of annotation comprises data of height, width, length, color, material of the store shelves;
generating a third set of simulation data, wherein the third set of simulation data describes store environments, wherein the third set of simulation data comprises a third set of annotations, wherein the third set of annotation comprises data of store ceiling, store setup, store floor and store lighting, wherein the data of the store lighting comprises data of color, intensity and style of the store lighting;
generating a fourth set of simulation data, where the fourth set of simulation data describes one or more customers, wherein the fourth set of simulation data comprises a fourth set of annotations, wherein the fourth set of annotation comprises data of height, weight, clothing style, hair color, gender, and interactions of the one or more customers with the products, the store shelves and the store environments;
generating a plurality of smart objects from the first set of simulation data, the second set of simulation data, the third set of simulation data, and the fourth set of simulation data, wherein each smart object represents a respective element of a virtual shopping environment that comprises at least one of a floor, a shelf, a sign, and a product, wherein the each smart object comprises a fifth set of annotations, wherein the fifth set of annotations comprises data of targeted location and targeted customer base of the retail store;
training and tuning the fifth set of annotations in a virtual reality simulation platform;
testing the plurality of smart objects in a simulated automatic store with an average amount of customers in the retail store, wherein the average amount is estimated from data gathered in surveys conducted in a local area;
testing the plurality of smart objects in another simulated automatic store with more than one hundred times of the average amount of customers in the retail store; and
testing the plurality of smart objects in a third simulated store with a size of ten times larger than that of the retail store.

2. The method of generating models of claim 1, wherein the style of the store lighting includes a style of disco lighting.

3. The method of generating models of claim 1, wherein the first set of annotations comprise transparency of a group of products.

4. The method of generating models of claim 1, wherein the fourth set of annotations further comprises total number and total value of products in a simulated store environment.

5. A method for simulating a retail store, comprising:
generating a first set of simulation data, wherein the first set of simulation data describes products, wherein the first set of simulation data comprises a first set of annotations, wherein the first set of annotations comprises data of product size, product shape, and possibility of one product partially covering another product;
generating a second set of simulation data, wherein the second set of simulation data describes store shelves, wherein the second set of simulation data comprises a second set of annotations, wherein the second set of annotation comprises data of height, width, length, color, material of the store shelves;
generating a third set of simulation data, wherein the third set of simulation data describes store environments, wherein the third set of simulation data comprises a third set of annotations, wherein the third set of annotation comprises data of store ceiling, store setup, store floor and store lighting, wherein the data of the store lighting comprises data of color, intensity and style of the store lighting;
generating a fourth set of simulation data, where the fourth set of simulation data describes one or more customers, wherein the fourth set of simulation data comprises a fourth set of annotations, wherein the fourth set of annotation comprises data of height, weight, clothing style, hair color, gender, and interactions of the one or more customers with the products, the store shelves and the store environments;
generating a plurality of smart objects from the first set of simulation data, the second set of simulation data, the third set of simulation data, and the fourth set of simulation data, wherein each smart object represents a respective element of a virtual shopping environment that comprises at least one of a floor, a shelf, a sign, and a product, wherein the each smart object comprises a fifth set of annotations, wherein the fifth set of annotations comprises data of targeted location and targeted customer base of the retail store;
training and tuning the fifth set of annotations of the plurality of smart objects in a virtual reality simulation platform; and
testing the plurality of smart objects in a simulated automatic store with an average amount of customers in the retail store, wherein the average amount of customers is estimated from data gathered in surveys conducted in a local area.

6. The method of differentiate products of claim 5, wherein the style of the store lighting includes a style of disco lighting.

7. The method of generating models of claim 5, wherein the first set of annotations comprise transparency of a group of products

8. The method of generating models of claim 5, wherein the fourth set of annotations further comprises total number and total value of products in a simulated store environment.

9. A method for simulating a virtual reality automatic store, comprising:
generating a first set of simulation data, wherein the first set of simulation data describes products, wherein the first set of simulation data comprises a first set of annotations;
generating a second set of simulation data, wherein the second set of simulation data describes store shelves, wherein the second set of simulation data comprises a second set of annotations;
generating a third set of simulation data, wherein the third set of simulation data describes store environments, wherein the store environments comprise store ceiling, store setup, store floor and store lighting, wherein the third set of simulation data comprises a third set of annotations;
generating a plurality of smart objects from the first set of simulation data, the second set of simulation data, and the third set of simulation data, wherein each smart object represents a respective element of the virtual shopping environment that comprises at least one of a floor, a shelf, a sign, and a product within the real-world shopping environment, wherein the each smart object comprises a fourth set of annotations;
training and tuning the fourth set of annotations of the plurality of smart objects in a virtual reality simulation platform; and
testing the plurality of smart objects in a real-world shopping automatic store.

10. The method of generating models of claim 9, wherein the first set of annotations comprise color, size, and position of the product.

11. The method of generating models of claim 9, wherein the second set of annotations comprise color, shape, and position of the shelf.

12. The method of generating models of claim 9, wherein the third set of annotations comprise size, shape of the virtual reality automatic store.
